(19) United States
(12) Patent Application Publication
(10) Pub. No.: US 2026/0309754 A1
(43) Pub. Date: Oct. 8, 2026

(54) CURRENT SENSING CAPABILITIES FOR POWER SEMICONDUCTOR DEVICES

(71) Applicant: Microchip Technology Incorporated, Chandler, AZ (US)

(72) Inventors: Cam Pham, Gistrup (DK); Yogesh Sharma, Colorado Springs, CO (US); Shesh Pandey, Gilbert, AZ (US)

(73) Assignee: Microchip Technology Incorporated, Chandler, AZ (US)

(21) Appl. No.: 19/246,182

(22) Filed: Jun. 23, 2025

Related U.S. Application Data
(60) Provisional application No. 63/784,699, filed on Apr. 7, 2025.

(51) Int. Cl. G01R 19/00; G01R 19/10; G01R 19/165

(52) U.S. Cl. CPC G01R 19/0092; G01R 19/10; G01R 19/16538

(57) ABSTRACT

A system, method, and apparatus providing current sensing capabilities for semiconductor devices. A method comprises sensing, through a first external connector of at least one semiconductor device package, a voltage on a first current path including a first semiconductor device of the at least one semiconductor device package; sensing, through a second external connector of the at least one semiconductor device package, a voltage on a second current path including a second semiconductor device of the at least one semiconductor device package; and detecting that a magnitude of current through the first current path is different from a magnitude of current through the second current path based on the voltage on the first current path and the voltage on the second current path.

### CROSS-REFERENCE TO RELATED APPLICATION

The present application claims priority to U.S. Provisional Patent Application No. 63/784,699, filed on Apr. 7, 2025, the contents of which are hereby incorporated by reference in their entirety.

### TECHNICAL FIELD

The present disclosure relates generally to power semiconductor devices, and more specifically to current sensing capabilities for power semiconductor devices.

### BACKGROUND

A power semiconductor device is an electronic component to efficiently and reliably control and convert electrical power at relatively high voltages and currents. Unlike regular signal-level semiconductors used in low-power applications, in some instances power semiconductor devices may be optimized for switching and amplifying large amounts of energy. Power semiconductor devices may be used in a variety of applications, such as motor drives, power supplies, renewable energy systems, electric vehicles, and the like.

### SUMMARY OF THE INVENTION

Aspects provide current sensing capabilities for semiconductor devices.

An aspect provides a system comprising a first current path comprising a first discrete semiconductor device, the first discrete semiconductor device comprising a first external connector to output a first voltage on the first current path; a second current path comprising a second discrete semiconductor device, the second discrete semiconductor device comprising a second external connector to output a second voltage on the second current path; and a detector coupled to the first external connector and the second external connector, the detector comprising circuitry to detect that a magnitude of current through the first current path is different from a magnitude of current through the second current path based on the first voltage and the second voltage.

Another aspect provides a semiconductor device package comprising at least one semiconductor device; and a plurality of connectors to connect the at least one semiconductor device to circuitry external to the at least one semiconductor device, wherein the plurality of connectors include a first connector connected to a first portion of the at least one semiconductor device, the first connector to output a voltage of the first portion of the at least one semiconductor device; and a second connector connected to a second portion of the at least one semiconductor device, the second connector to output a voltage of the second portion of the semiconductor device, wherein relative magnitudes of the voltage of the first portion and the voltage of the second portion are indicative of relative currents through the first portion and the second portion.

Another aspect provides a method comprising sensing, through a first external connector of at least one semiconductor device package, a voltage on a first current path including a first semiconductor device of the at least one semiconductor device package; sensing, through a second external connector of the at least one semiconductor device package, a voltage on a second current path including a second semiconductor device of the at least one semiconductor device package; and detecting that a magnitude of current through the first current path is different from a magnitude of current through the second current path based on the voltage on the first current path and the voltage on the second current path.

### BRIEF DESCRIPTION OF THE DRAWINGS

FIG. 1 illustrates a system with current sensing capabilities for at least one semiconductor device, in accordance with any of the examples disclosed herein.

FIG. 2 illustrates circuitry comprising voltage outputs for two current paths including respective semiconductor devices, in accordance with any of the examples disclosed herein.

FIG. 3 illustrates voltage and current waveforms for the circuity of FIG. 2, in accordance with any of the examples disclosed herein.

FIG. 4 illustrates two semiconductor devices with respective voltage outputs, in accordance with any of the examples disclosed herein.

FIG. 5 illustrates a power module comprising circuitry comprising two current paths with voltage outputs, in accordance with any of the examples disclosed herein.

FIG. 6 illustrates a semiconductor device that includes a pair of voltage outputs, in accordance with any of the examples disclosed herein.

FIG. 7 illustrates at least one semiconductor device with voltage outputs on conductive pads with different geometries, in accordance with any of the examples disclosed herein.

FIG. 8 illustrates schematics of example implementations of the at least one device of FIG. 7, in accordance with any of the examples disclosed herein.

### DETAILED DESCRIPTION

In many systems, in order to sense current in a power semiconductor device, such as a power metal-oxide-semiconductor field-effect transistor (MOSFET), a small, low-resistance resistor commonly referred to as a current sense resistor is placed in series with the device (e.g., in a MOSFET's drain current path). The current sense resistor experiences a small voltage drop based on the current flowing through it, enabling measurement of the current with a dedicated circuit that monitors the voltage drop across the current sense resistor.

A semiconductor device may include a plurality of terminals (e.g., in the case of a MOSFET the terminals may include a source, a gate, and a drain while in the case of a diode the terminals may include an anode and a cathode). In this sense, a terminal may refer generally to one or more areas of electrical connection for a device. A semiconductor device package that includes one or more semiconductor devices may include a plurality of external connectors (e.g., pins, conductive pads, or other conductive structures) for connecting the semiconductor device package to circuitry that is external to the semiconductor device package. For example, the external connectors of a semiconductor device package may be connected to a printed circuit board (PCB) through soldered connections, a socket, or other means and coupled to discrete components, one or more other semiconductor device packages, or other circuitry on the PCB. In some instances, an external connector of a semiconductor device package may be connected to one or more terminals of one or more semiconductor devices of the semiconductor device package, e.g., via one or more wire bonds or a lead frame.

As an example, a first wire bond may connect to a first portion of an external connector and a first portion of a terminal, a second wire bond may connect to a second portion of the external connector and a second portion of the terminal, and so on (with additional wires bonds increasing the current capacity of the connection between the external connector and the terminal). As another example, a terminal may be connected to an external connector through other means. For example, a terminal of a device (e.g., a drain of a MOSFET) may be placed upon a lead frame (and connected to the lead frame through lead solder wire, solder paste, or other conductive material) that is connected to the corresponding external connector (e.g., a pin that extends outward from the lead frame).

In some instances, a semiconductor device package may include an external connector (e.g., pin) known as a Kelvin connection. The Kelvin connection may connect to a portion of a terminal of a semiconductor device (e.g., a source or drain of a MOSFET). The terminal may also be connected (e.g., at another portion of the terminal) to another external connector, but the Kelvin connection may avoid stray inductance or other parasitic effects encountered through accessing the terminal through the other external connector(s). In a MOSFET, a Kelvin connection may typically be used to drive the transistor on and off (e.g., through the setting of a particular gate-to-source voltage) while avoiding stray inductance (e.g., that could be encountered through the external connector for the source terminal).

In various examples of the present disclosure, a system may include current paths with sense locations that provide voltage outputs (e.g., provided via Kelvin connections) that are monitored to detect current flows within the system based on the voltages. The voltages may be indicative of the relative current flow in the current paths. In some instances, the voltages may indicate an excessive current event occurring in one of the current paths In some instances, when an excessive current event is detected, remedial action may be taken to protect the system or a component thereof.

In one example, a system includes a first power semiconductor device and a second power semiconductor device and utilizes a Kelvin connection of the first power semiconductor device to sense a voltage of a first current path and a Kelvin connection of the second power semiconductor device to sense a voltage of a second current path. In another example, a power semiconductor device includes two connections to output voltages of different portions of the device to enable detection of current through the different portions.

Various examples of the present disclosure may provide one or more technical advantages, such as an improved signal for current detection (e.g., with common mode noise filtered out due to the differential signal between the two sensed voltages), reduced circuitry for current detection (e.g., by omitting a current sense resistor), improved certainty and repeatability in detecting excessive current events, or other improvements.

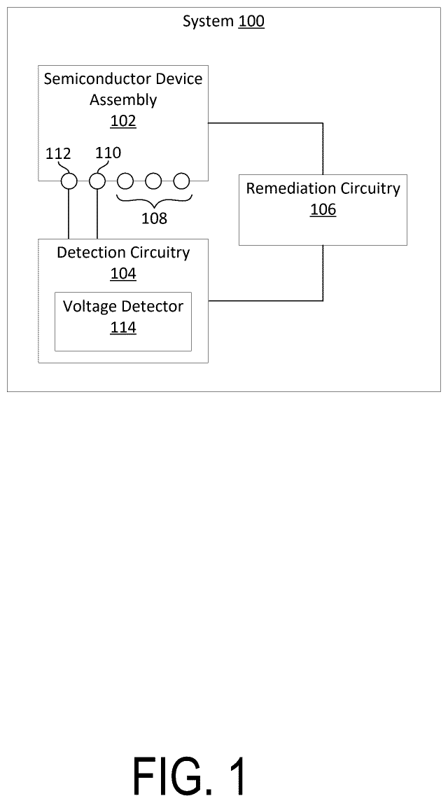

FIG. 1 illustrates a system 100 with current sensing capabilities for at least one semiconductor device of the semiconductor device assembly 102, in accordance with any of the examples disclosed herein. The system 100 includes semiconductor device assembly 102, detection circuitry 104, and remediation circuitry 106.

In various examples, the semiconductor device assembly 102 includes one or more semiconductor devices formed on one or more dies comprising substrates (e.g., comprising silicon, silicon carbide, gallium nitride, or the like). In some instances, the semiconductor devices may include one or more power semiconductor devices. A power semiconductor device may include any suitable semiconductor device that can accommodate high voltage (e.g., between 10V-8000V, but not limited thereto) applied to one or more terminals or high current (e.g., between 5 A-1000 A, but not limited thereto) flowing through one or more terminals. As examples, a power semiconductor device may comprise a metal-oxide-semiconductor field-effect transistor (MOSFET), a junction field-effect transistor (JFET), an insulated gate bipolar transistor (IGBT), a bipolar junction transistor (BJT), a thyristor, a diode, or the like.

In some examples, the semiconductor device assembly 102 includes a single discrete semiconductor device. For example, the semiconductor device assembly 102 may be a packaged semiconductor device in which the external connectors of the package connect to terminals of the single semiconductor device. As another example, the semiconductor device assembly 102 may be a die including a single semiconductor device with pads for terminals of the single semiconductor device. In some instances, the die may be mounted to a substrate or printed circuit board (PCB).

In other examples, the semiconductor device assembly 102 includes a plurality of semiconductor devices on the same die or on multiple dies (e.g., coupled together). In one example, the semiconductor device assembly 102 includes a semiconductor device package that includes multiple dies (with respective semiconductor devices) within the package. In another example, the semiconductor device assembly 102 includes a plurality of semiconductor device packages coupled together, where respective packages have at least one semiconductor device. In yet another example, the semiconductor device assembly 102 may include a power module comprising a plurality of power semiconductor devices on multiple dies arranged in an electronic circuit or portion thereof (optionally with additional circuitry, such as inductors, capacitors, or resistors). For example, the power module may comprise a half-bridge module, a full-bridge module, a six-pack module, a power integrated module, or other suitable module type.

A semiconductor device package may have any suitable form factor, such as a through-hole package, a surface-mount package, a dual in-line package, or other suitable form factor.

In various examples, the semiconductor device assembly 102 may include external connectors (e.g., pins, pads, or other conductive structures) to connect one or more dies or packages of the semiconductor device assembly 102 to other circuitry of system 100. As just one example, the semiconductor device assembly 102 may be connected to a PCB and may be coupled through conductive traces of the PCB to other circuitry or packages comprising circuitry.

In the example depicted, the external connectors of the semiconductor device assembly 102 include control connectors 108, sense connector 110, and sense connector 112. These connectors may connect to corresponding terminals of the semiconductor device assembly 102. For example, when the semiconductor device assembly 102 includes a discrete MOSFET or JFET, the control connectors 108 may be respectively coupled to gate, source, and drain terminals. As another example, when the semiconductor device assembly 102 includes a discrete BJT, the control connectors 108 may be coupled to emitter, base, and collector terminals. As another example, when the semiconductor device assembly 102 includes an IGBT, the control connectors 108 may be coupled to gate, collector, and emitter terminals. As another example, when the semiconductor device assembly 102 includes a thyristor, the control connectors 108 may be coupled to anode, cathode, and gate terminals.

Although three control connectors 108 are shown, the semiconductor device assembly 102 may include any suitable number of control connectors. For example, multiple control connectors may connect to the same terminal of the semiconductor device assembly 102 (e.g., a source terminal of a particular transistor may connect to two control connectors). As another example, multiple devices within the semiconductor device assembly 102 may each have terminals that connect to a respective set of control connectors.

In some instances, one or more control connectors 108 may be connected to one or more components or systems controlled by or powered by the semiconductor device assembly 102. For example, one or more control connectors 108 may be coupled to an inverter, converter, motor, power supply, or other component or system.

In an example in which the semiconductor device assembly 102 includes a plurality of semiconductor devices, the first sense connector 110 may be connected to a terminal of a first semiconductor device (e.g., at a source, drain, collector, emitter, anode, cathode, or other terminal of the device) and the second sense connector 112 may be connected to a terminal of the second semiconductor device. In some examples the sense connectors 110 may be connected to the same terminal of the respective devices (for example, respective source terminals of the devices or respective drain terminals of the devices), while in other examples the sense connectors may be connected to different terminals (e.g., one sense connector may be connected to a source terminal of a first transistor while the other sense connector may be connected to a drain terminal of a second transistor). In various examples, the terminals connected to the sense connectors are in parallel circuitry paths within the semiconductor device assembly 102.

When the semiconductor device assembly 102 includes a single discrete semiconductor device, the first sense connector 110 may be connected to a first portion of a terminal of the semiconductor device and the second sense connector 112 may be connected to the same terminal at a second portion of the terminal.

The system 100 also includes detection circuitry 104 that is connected to the first sense connector 110 and second sense connector 112. Detection circuitry 104 includes a voltage detector 114. The voltage detector is operable to detect a differential voltage between the first sense connector 110 and the second sense connector 112. This voltage is indicative of an amount of current through at least one semiconductor device of the semiconductor device assembly 102. In some instances, the detection circuitry 104 may include circuitry to amplify the differential signal between first sense connector 110 and second sense connector 112 (e.g., if the level of the signal is relatively small) or to provide an offset voltage for the differential signal if the sense connectors are coupled at locations that are expected to have different quiescent voltages (e.g., if one sense connector is connected to a drain terminal of one device in a current path and the other sense connector is connected to a source terminal of another device in a similar current path).

In some instances, the detection circuitry 104 may be coupled to a circuit board (e.g., PCB) that is also coupled to the semiconductor device assembly 102. In other examples, the first sense connector 110 and second sense connector 112 may be coupled to the detection circuitry 104 in any other suitable manner, including, e.g., being integrated together on the same die or disposed within the same package.

The system 100 also includes remediation circuitry 106 which may be operable to perform a remedial action when an excessive current condition is detected by the detection circuitry 104. For example, remediation circuitry 106 may be operable to shut down the semiconductor device that is experiencing excessive current (e.g., through tripping of a fuse or other suitable action). As another example, the remediation circuitry 106 may shut down a component or system coupled to (e.g., and powered by) the system 100 or prevent the component or system from starting when the excessive current condition is detected. In other examples, the detection of the current may be used by any suitable circuitry to regulate, calibrate, or perform diagnosis.

In some instances, the remediation circuitry 106 may be coupled to the semiconductor device assembly 102 through one or more of the control connectors 108 or in other suitable manner. In some instances, the remediation circuitry 106 may be coupled to a circuit board that is also coupled to the semiconductor device assembly 102 and detection circuitry 104. In other examples, the first sense connector 110 and second sense connector 112 may be coupled to the semiconductor device assembly 102 or detection circuitry 104 in any other suitable manner (e.g., they may be connected together within the same package).

In some instances, all or a portion of either detection circuitry 104 or remediation circuitry 106 may be located within semiconductor device assembly 102. In such an instance, a terminal being sensed does not necessarily have to connect to an external connector (e.g., sense connector 110 or 112), but rather may be connected directly to the relevant circuitry of the detection circuitry 104 or remediation circuitry 106.

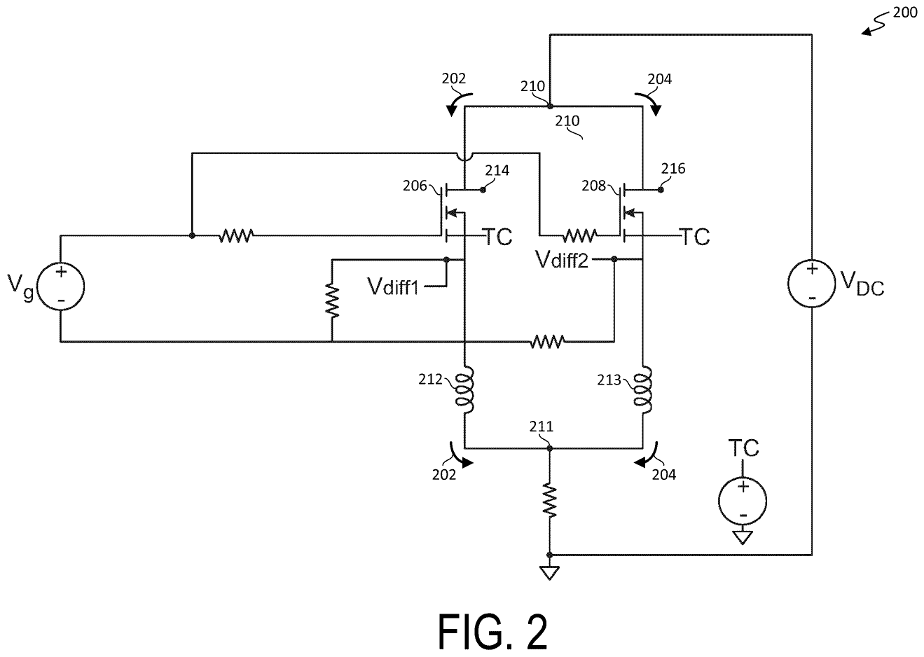

FIG. 2 illustrates circuitry 200 comprising sense locations output voltages Vdiff1 and Vdiff2 on two current paths 202 and 204 including respective semiconductor devices 206 and 208, in accordance with any of the examples disclosed herein. All or a portion of the circuitry 200 may be included within a semiconductor device assembly 102.

In this example, the current entering node 210 is split between two parallel branches (also referred to herein as current paths) from node 210 to node 211, wherein each branch includes one or more semiconductor devices or other circuitry. In some instances, the current paths may be designed similarly, such that they include the same circuit elements. For example, current path 202 includes a semiconductor devices 206 in series with an inductance 212, while current path 204 includes a similarly sized semiconductor devices 208 and a similarly sized inductance 213 (in some instances, the inductances or impedances in a current path may be stray inductances or impedances, rather than discrete inductors or resistors). In other examples, the circuitry could include additional parallel branches without impeding the ability to sense relative current based on Vdiff1 and Vdiff2.

As the semiconductor devices 206 and 208 (illustrated here as MOSFETs) or their respective current paths may have some sort of physical imbalance or mismatch (whether through parasitic effects or through the fabrication process), they may not always experience the same current flow (even despite having similar designs). Thus, such an imbalance could trigger an excessive current event on one of the semiconductor devices, which could be harmful or otherwise problematic to the semiconductor devices themselves or to circuitry or other components coupled to the semiconductor devices (e.g., through outputs 214 and 216).

A first sense location on the first current path 202 is located on the source terminal of the semiconductor devices 206 and a second sense location on the second current path 204 is located on the source terminal of the semiconductor devices 208. The first sense location outputs a first voltage Vdiff1 and the second sense location outputs a second voltage Vdiff2. In a physical implementation, the first sense location may be connected to a first external connector (e.g., first sense connector 110) while the second sense location may be connected to a second external connector (e.g., second sense connector 112) of a semiconductor device assembly 102.

The voltage Vdiff1 and the voltage Vdiff2 may be analyzed as a differential signal to sense whether the magnitude of current through the first current path 202 (and the semiconductor devices 206) is different from the magnitude of current through the second current path 204 (and the semiconductor devices 208). The difference between Vdiff1 and Vdiff2 may be indicative of the different in current through the first current path and second current path. When Vdiff1 and Vdiff2 are the same magnitude or substantially the same magnitude, the currents through the paths may be equal or substantially equal. When Vdiff1 is higher than Vdiff2, the magnitude of current through current path 202 may be higher than the magnitude of current through current path 204 (and the magnitude of the current difference scales with the voltage difference). Conversely, when Vdiff2 is higher than Vdiff1, the magnitude of current through current path 204 may be higher than the magnitude of current through current path 202 (and the magnitude of the current difference scales with the voltage difference).

In some examples, the sense locations may be sensed to determine whether an excessive current event is occurring (e.g., whether the current is significantly imbalanced between the first current path 202 including the first semiconductor device 206 and the second current path 204 including a second semiconductor device 208). As an example, an excessive current event may occur when the current through one branch is more than the current through the other branch by a threshold amount, as indicated by the differential voltage between Vdiff1 and Vdiff2 exceeding a particular magnitude.

In the circuitry illustrated, the sense locations outputting Vdiff1 and Vdiff2 are located at the source terminals of semiconductor devices 206 and 208, but in other examples the sense locations providing the differential signal may be at any other suitable positions within the circuitry, such as the drain terminals or other positions. For example, one sense location may be at the drain of semiconductor devices 206 and one sense location may be at the drain of 208. As another example, one sense location may be at the source terminal of semiconductor devices 206 and the other sense location may be at the drain terminal of semiconductor devices 208. In some instances, one or more of the sense locations may be at any other floating potential of either current path, such as the bottom side of the inductance 212 or 213. When the relative locations of the sense locations are different, then Vdiff1 may have a different steady state magnitude than Vdiff2 due to resistance/impedance differences. In such instances, the detection circuitry 104 or other portion of system 100 may include circuitry to account for this offset when comparing Vdiff1 to Vdiff2. For example, when one sense location is at a drain terminal of semiconductor devices 206 and one sense location is at a source terminal of semiconductor devices 208, a drain to source voltage offset (e.g., V_{DS} on) may be applied such that Vdiff1 and Vdiff2 are substantially equal when being compared in a steady state.

In various examples, any suitable portions of the circuitry 200 may be included within semiconductor device assembly 102 while other portions may be included in system 100 outside of the semiconductor device assembly 102 (e.g., on a PCB). For example, the semiconductor devices 206 and 208 may be included within semiconductor device assembly 102 while the power supplies (V_{DC} and V_{g}) may be included outside of 102 (e.g., and provided to the 102 via respective control connectors 108). In some examples, semiconductor devices 206 and semiconductor devices 208 may be discrete devices (e.g., they may be the only semiconductor devices on respective dies or within respective packages). In one example, the sense location providing Vdiff1 is connected to a Kelvin connection of semiconductor devices 206 (for example, an external pin of a package comprising semiconductor devices 206 or an external pad of a die comprising semiconductor devices 206) and the sense location providing Vdiff2 is connected to a Kelvin connection of semiconductor devices 208 (for example, an external pin of a package comprising semiconductor devices 208 or an external pad of a die comprising semiconductor devices 208).

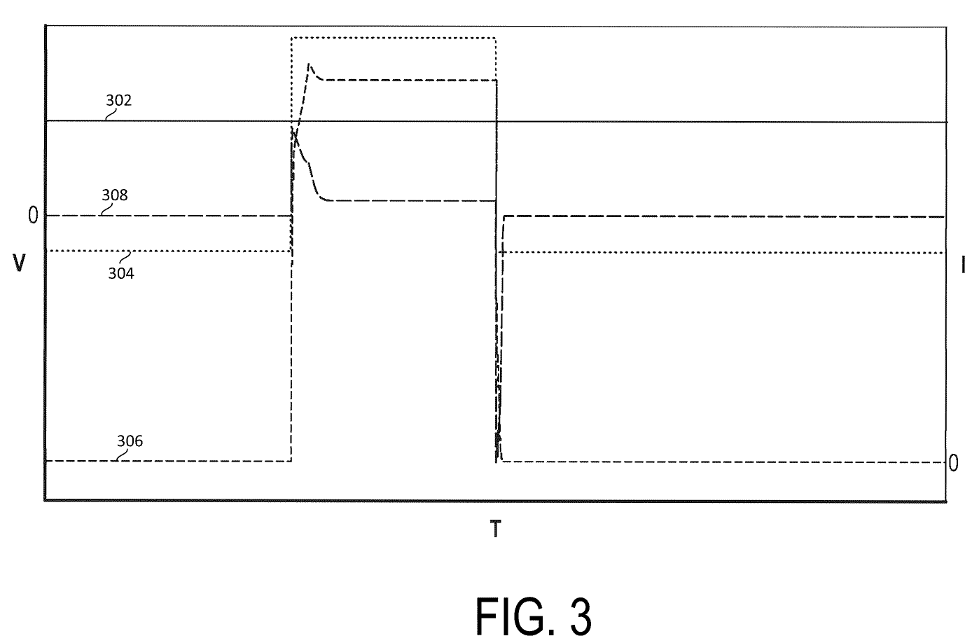

FIG. 3 illustrates voltage and current waveforms for the circuitry 200 of FIG. 2, in accordance with any of the examples disclosed herein. The left y-axis depicts voltage, the right y-axis depicts current, and the x-axis depicts time. Waveform 302 corresponds to V_{DC} and is constant in magnitude for the duration of the period being shown. Waveform 304 corresponds to V_{g}, a voltage applied to the gates of the transistors to turn the transistors on and then off. Waveform 306 corresponds to a current from V_{DC} and rises precipitously responsive to application of V_{g} and then falls back to a steady state value when V_{g} drops. Waveform 308 corresponds to the differential signal between Vdiff1 and Vdiff2 and indicates differences in current conduction of the current paths 202 and 204.

Waveform 308 rises at the same time as waveform 306. The rise in the differential signal of waveform 308 indicates that one semiconductor device is experiencing a voltage drop that is not experienced by the other transistor. Accordingly, a larger amount of current is flowing through the current path that includes that semiconductor device than is flowing through the other current path that includes the other semiconductor device. The current difference is proportional to the voltage differential. Accordingly, a relatively large voltage differential may indicate that an excessive current condition is occurring with respect to one of the semiconductor devices and (in some examples) remedial action may be initiated.

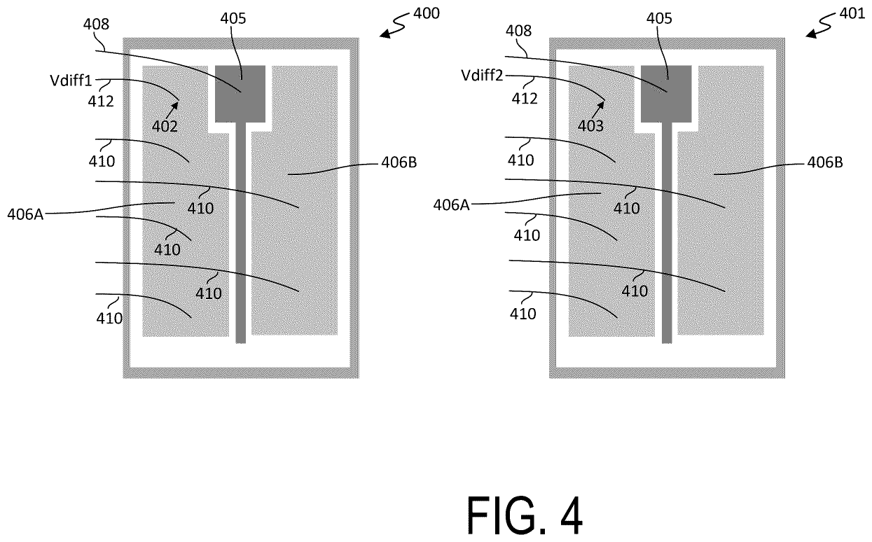

FIG. 4 illustrates two semiconductor devices 400 and 401 with respective voltage outputs Vdiff1 and Vdiff2 from sense locations 402 and 403, in accordance with any of the examples disclosed herein. These devices 400 and 401 may be included within semiconductor device assembly 102. As one example, device 400 may correspond to semiconductor devices 206 (or other semiconductor device described herein that is to provide a sensed voltage Vdiff1) and device 401 may correspond to semiconductor devices 208 (or other semiconductor device described herein that is to provide a sensed voltage Vdiff2).

In some examples, the device 400 and device 401 may be included within a semiconductor device assembly 102. In this example, the devices 400 and 401 are each represented as a transistor on a die, where the die includes source pads 406A and 406B (which may be electrically connected together in one or more layers that are not shown) to implement at least a portion of the source terminal of the transistor. The die may also include a gate pad 405 and a conductive line extending from the gate pad (e.g., to couple to various cells of the transistor). The devices 400 and 401 may also include drain terminals (not shown) which may be located, e.g., on the underside of the devices 400 and 401 (where the views of FIG. 4 are top-down views).

In this example, device 400 includes a sense location 402 that is to provide Vdiff1 and a sense location 403 that is to provide Vdiff2. In this example, the sense locations are located on the material that makes up the respective source terminals of the devices 400, 401.

In the example depicted, the devices 400, 401 are connected to various wire bonds 408, 410, and 412 that may connect portions of the devices to external connectors (e.g., 108, 110, 112). For example, wire bond 408 may connect the gate pad 405 of device 400 to a gate pin of a semiconductor package comprising device 400, wire bonds 410 may connect the source pads 406A, 406B of device 400 to a source pin of the semiconductor package, and wire bond 412 may connect the sense location 402 (of the source pad 406A) of device 400 to a Kelvin connection pin (sometimes referred to as a Kelvin terminal) of the semiconductor package. Similarly, wire bonds connected to device 401 may connect various portions of device 401 to pins of a semiconductor package comprising device 401. In some instances, devices 400, 401 may be packaged in their own semiconductor device packages or could be on dies that are packaged together into a single semiconductor device package (and that package may have respective pins for each device 400).

In some examples, in addition to providing a connection to measure the differential signal as explained above, the sense location and the external connector that is connected to the sense location may also be used to drive the device on and off by applying a voltage to the source terminal that is used to achieve a desired gate-to-source voltage (as stray inductance may result in a voltage drop if the device is driven on and off through the source pin connected to the wire leads 410). In some examples in which the sense location 402 is on the drain terminal instead of the source terminal, the sense location and corresponding pin is not used to drive the device on and off (but is only used for sensing the respective Vdiff1 or Vdiff2 voltage).

In various examples, portions of the top of the source pad will be open with bare metallization for the wire bonding or other attachment, but other areas (e.g., represented by the border around the blocks of the source pad) may be covered by a protective material (e.g., polyimide), e.g., to protect against moisture.

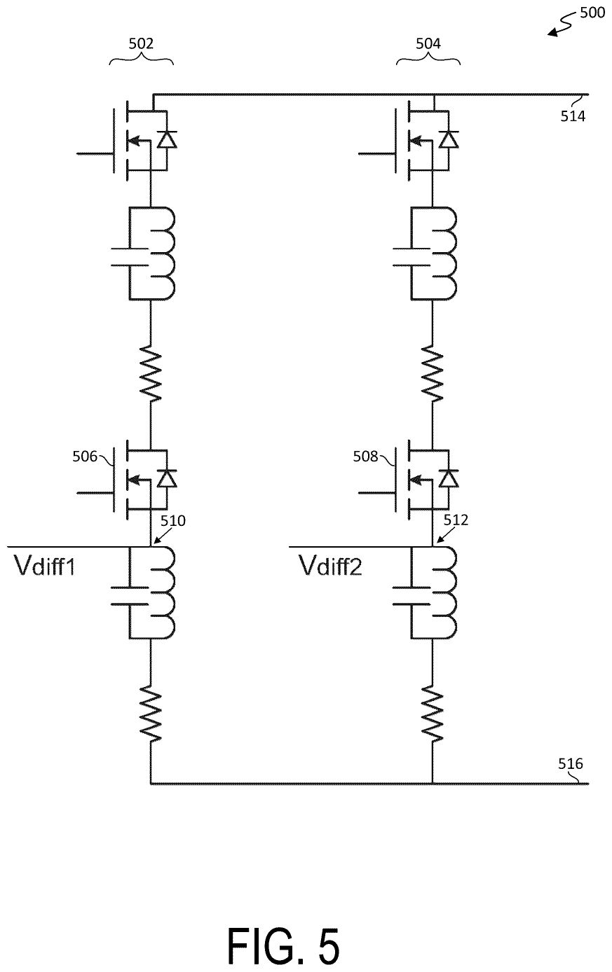

FIG. 5 illustrates a power module 500 comprising two parallel current paths 502 and 504 with semiconductor devices 506 and 508 and sense locations 510 and 512 outputting voltages Vdiff1 and Vdiff2, in accordance with any of the examples disclosed herein. The circuitry of FIG. 5 depicts a full bridge that may be included within a power module or other packaged device of a semiconductor device assembly 102. The sense locations 510 and 512 may be connected, e.g., to first sense connector 110 and second sense connector 112 respectively. In some examples, the outputs 514 and 516 of the full bridge may be connected to control connectors 108. In some examples, the semiconductor devices 506 and semiconductor devices 508 may be implemented by devices 400 and devices 401 (or other suitable semiconductor devices with sense locations for Vdiff1 and Vdiff2).

As in the example above of FIG. 2, the current paths 502 and 504 each include at least one semiconductor device and other circuitry. For example, two parallel current paths 502 includes (in series) a first transistor, a capacitance and inductance in parallel, a resistance, semiconductor device 506, another capacitance and inductance in parallel and a resistance. Two parallel current paths 504 includes a similar set of components.

In this example, the sense locations 510 are again located at source terminals of the respective semiconductor devices 506 and 508, although in other examples they may be located at other portions of the current paths. In a similar manner to that described above, the differential voltage between Vdiff1 and Vdiff2 may be indicative of the relative amount of current flowing in the paths 502 and 504.

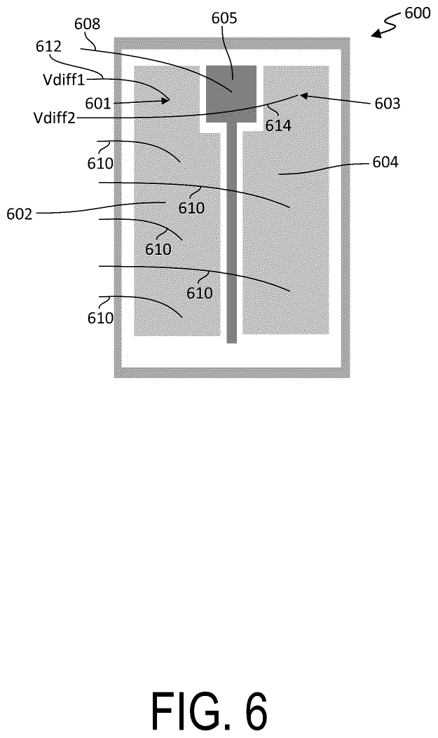

FIG. 6 illustrates a die 600 comprising a semiconductor device that includes a pair of sense locations 601 and 603 to provide voltage outputs Vdiff1 and Vdiff2, in accordance with any of the examples disclosed herein. In some instances, semiconductor device assembly 102 may include a single discrete transistor, such as is represented by the semiconductor device of die 600. Sense location 601 may be connected (e.g., via wire bond 612) to first sense connector 110 and sense location 603 may be connected (e.g., via wire bond 614) to second sense connector 112.

Die 600 may include a gate pad 605 and a conductive line extending from the gate pad. A wire bond 608 may connect the gate pad to another conductive structure (e.g., to an external connector 108). Die 600 also includes source pads 602 and 604, with wire bonds 610 connecting the source pads 602 and 604 to another conductive structure (e.g., to an external connector 108). In some instances, the die 600 may also include a drain terminal on its bottom side.

As just one example, semiconductor device assembly 102 may be a semiconductor device package including a single die 600 comprising the semiconductor device (e.g., a power MOSFET) with five pins: a pin to connect to the source terminal, a pin to connect to the drain terminal, a pin to connect to the gate terminal, a pin to connect to sense location 601, and a pin to connect to sense location 603.

Physical imperfections may exist within the device of die 600, such that addition of a second sense location may allow sensing of a differential signal with the two sense locations that exhibits a small, but detectable, voltage drop (e.g., from a location of one source pad 602 connected to Vdiff1 to a location of another source pad 604 connected to Vdiff2, even when the source pads are connected together at another portion of the 600, such as below the visible layer). As in the examples above, this voltage differential may be indicative of the relative magnitudes of current flowing through the respective sense locations.

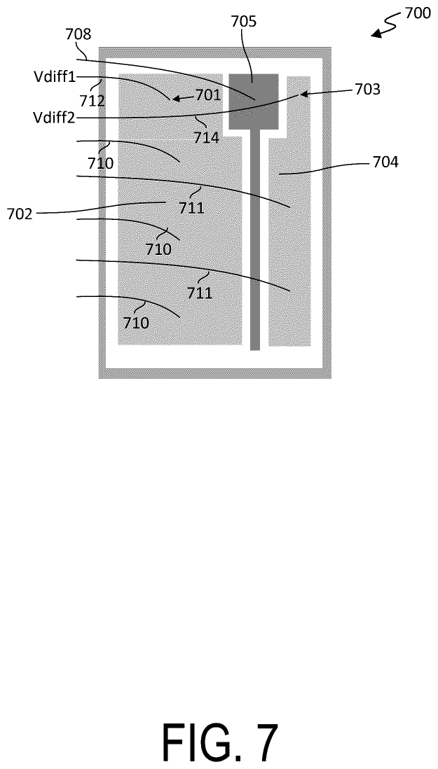

FIG. 7 illustrates a die 700 comprising at least one semiconductor device that includes a pair of sense locations 701 and 703 to provide voltage outputs Vdiff1 and Vdiff2, in accordance with any of the examples disclosed herein. In this example, conductive pads of the die 700 include different geometries and sizes. In one example, die 700 includes a single semiconductor device (e.g., where conductive pads 702 and 704 are source pads with different sizes.

In another example, the die 700 includes a pair of semiconductor devices that share a common substrate. In this example, the conductive pad 705 (e.g., a gate pad) may be shared between the two devices, while the conductive pads 702 and 704 (e.g., source pads) are discrete pads for the two devices. That is, they are not connected to each other. Rather conductive pad 702 is part of a first semiconductor device and conductive pad 704 is part of a second semiconductor device. In this example, conductive pad 702 may be connected to another conductive structure (e.g., an external connector 108) via wire bonds 710 while conductive pad 704 may be connected to another conductive structure (e.g., a different external connector 108) via wire bonds 711.

In this example, sense location 701 is on a portion of the conductive pad 702 and may be connected to an external connector 110 through wire bond 712. Sense location 703 is on a portion of the conductive pad 704 and may be connected to an external connector 112 through wire bond 714.

In at least some examples, a drain pad (e.g., at the bottom of the die) may be shared between the two devices. In some examples, the devices may have different R_{DS} on values or other differing characteristics.

As in the examples above, the voltage differential between Vdiff1 and Vdiff2 may be indicative of the relative magnitudes of current flowing through the respective sense locations (and thus through the respective semiconductor devices of the die 700). In the case where die 700 includes a single transistor, the voltage differential may be indicative of the relative magnitudes of current flowing through the respective sense locations.

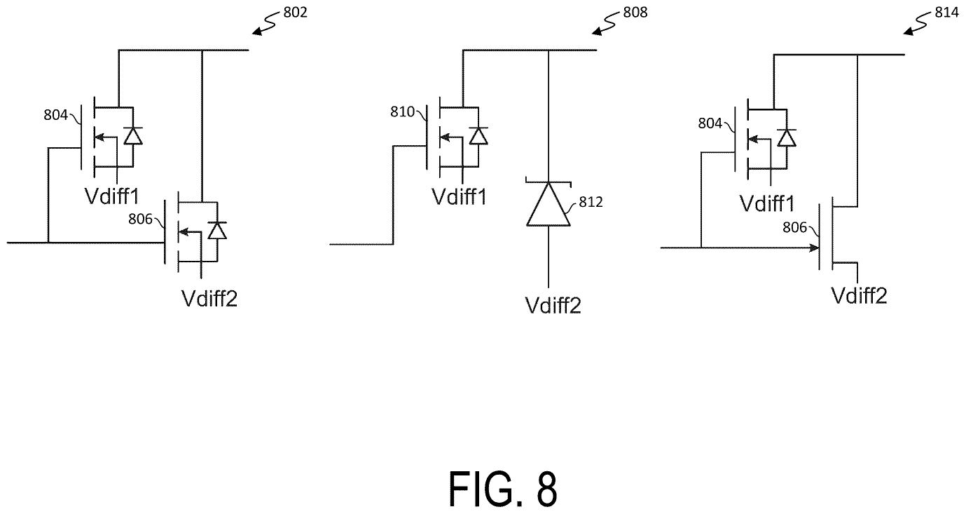

FIG. 8 illustrates schematics of example implementations of the die 700 of FIG. 7 when the die comprises a pair of semiconductor devices, in accordance with any of the examples disclosed herein. In schematic 802, the die 700 includes a first MOSFET 804 and a second MOSFET 806. The two MOSFETs may share the conductive pad 705 (e.g., a gate pad) and the drain pad of die 700. Consistent with FIG. 7, Vdiff1 is the output of a sense location on the source terminal of the MOSFET 804 and Vdiff2 is the output of a sense location on the source terminal of the MOSFET 806.

In schematic 808, the die 700 includes a MOSFET 810 and a Schottky barrier diode 812. The conductive pad 705 is connected to the gate of the MOSFET 810. The conductive pad 702 and the sense location 701 is connected to the source terminal of the MOSFET 810. The conductive pad 704 and the sense location 703 is connected to the anode of the 812. A conductive pad (e.g., on the bottom of the die) may be connected to both the drain of the MOSFET 810 and the cathode of the Schottky barrier diode 812.

In schematic 814, the die 700 includes a MOSFET 816 and a JFET 818. The MOSFET 816 and the JFET 818 may share the conductive pad 705 (e.g., a gate pad) and the drain pad of die 700. Consistent with FIG. 7, Vdiff1 is the output from a sense location on the source terminal of the MOSFET 816 and Vdiff2 is the output from a sense location on the source terminal of the JFET 818.

In other examples, any suitable power semiconductor devices may be included together on the same substrate. For example, one of more of the devices of FIG. 8 may be replaced with a device having similar terminals or functionality.

As used herein, the term “or” is intended to be inclusive rather than exclusive. That is, unless otherwise indicated or as would be apparent to one of skill in the art, the use of “or” should be interpreted to mean “and/or.” For example, the phrase “A or B” should be understood to mean “A, B, or both A and B.” The singular terms “a,” “an,” and “the” are intended to encompass their plural counterparts as well, unless it is clear from the context that a different interpretation is intended. Herein, when a list of items is preceded by phrases such as “at least one of” or “one or more of,” it is intended to allow for any combination of the listed elements.

The terms “over,” “under,” “between,” and “on,” as used herein, describe the relative positioning of components or materials. For instance, one layer being over or under another layer may encompass direct contact of the layers or the presence of one or more intermediate layers. Similarly, a layer described as being between two others may be in contact with both other layers or separated by one or more additional layers. Conversely, when a layer is “on” another layer, at least a portion of the layer is in direct physical contact with the underlying layer.

In the drawings, while some structural or method features may be shown in specific arrangements or orderings, such specific arrangements or orderings may be optional. In some examples, such features may be arranged in a different manner or order than shown in the drawings. Additionally, the inclusion of a structural or method feature in a particular drawing is not meant to imply that such feature is present in all examples, and, in some examples, such feature may not be included or may be combined with other features. Further, the various examples shown in the drawings are illustrative representations and may not be drawn to scale. In some instances, the same or similar reference numerals may be used to designate the same or similar features in different drawings.

Example 1 includes a system comprising a first current path comprising a first discrete semiconductor device, the first discrete semiconductor device comprising a first external connector to output a first voltage on the first current path; a second current path comprising a second discrete semiconductor device, the second discrete semiconductor device comprising a second external connector to output a second voltage on the second current path; and a detector coupled to the first external connector and the second external connector, the detector comprising circuitry to detect that a magnitude of current through the first current path is different from a magnitude of current through the second current path based on the first voltage and the second voltage.

Example 2 includes the subject matter of Example 1, and further including circuitry to perform an action to protect the first discrete semiconductor device or the second discrete semiconductor device responsive to detection of an excessive current condition based on the first voltage and the second voltage.

Example 3 includes the subject matter of any of Examples 1 and 2, and wherein the first current path is in parallel with the second current path.

Example 4 includes the subject matter of any of Examples 1-3, and wherein during a steady state condition, the first voltage is equal to the second voltage, and wherein during a switching or transient load event, the first voltage is different from the second voltage.

Example 5 includes the subject matter of any of Examples 1-4, and wherein the first external connector is connected to a source terminal of the first discrete semiconductor device and the second external connector is connected to a source terminal of the second discrete semiconductor device.

Example 6 includes the subject matter of any of Examples 1-5, and wherein the first external connector is connected to a drain terminal of the first discrete semiconductor device and the second external connector is connected to a drain terminal of the second discrete semiconductor device.

Example 7 includes the subject matter of any of Examples 1-6, and wherein the first semiconductor device is one of a metal-oxide-semiconductor field-effect transistor (MOSFET), a junction field-effect transistor (JFET), an insulated gate bipolar transistor (IGBT), a bipolar junction transistor (BJT), or a thyristor.

Example 8 includes a semiconductor device package comprising at least one semiconductor device; and a plurality of connectors to connect the at least one semiconductor device to circuitry external to the at least one semiconductor device, wherein the plurality of connectors include a first connector connected to a first portion of the at least one semiconductor device, the first connector to output a voltage of the first portion of the at least one semiconductor device; and a second connector connected to a second portion of the at least one semiconductor device, the second connector to output a voltage of the second portion of the semiconductor device, wherein relative magnitudes of the voltage of the first portion and the voltage of the second portion are indicative of relative currents through the first portion and the second portion.

Example 9 includes the subject matter of Example 8, and wherein the at least one semiconductor device comprises a transistor and wherein a source terminal of the transistor comprises the first portion and the second portion.

Example 10 includes the subject matter of any of Examples 8 and 9, and wherein the at least one semiconductor device comprises a transistor and wherein an emitter terminal of the transistor comprises the first portion and the second portion.

Example 11 includes the subject matter of any of Examples 8-10, and wherein the first connector is connected to a first portion of a conductive pad, and wherein a third connector of the plurality of connectors is connected to a second portion of the conductive pad.

Example 12 includes the subject matter of any of Examples 8-11, and wherein the second connector is connected to a first portion of a second conductive pad, and wherein a fourth connector of the plurality of connectors is connected to a second portion of the second conductive pad.

Example 13 includes the subject matter of any of Examples 8-12, and wherein the second conductive pad has a smaller top surface area than the conductive pad.

Example 14 includes the subject matter of any of Examples 8-13, and wherein the at least one semiconductor device comprises a first MOSFET and a second MOSFET, and wherein the first connector is connected to a source of the first MOSFET and the second connector is connected to a source of the second MOSFET.

Example 15 includes the subject matter of any of Examples 8-14, and wherein the at least one semiconductor device comprises a MOSFET and a Schottky barrier diode, and wherein the first connector is connected to a source of the first MOSFET and the second connector is connected to an anode of the Schottky barrier diode.

Example 16 includes a method comprising sensing, through a first external connector of at least one semiconductor device package, a voltage on a first current path including a first semiconductor device of the at least one semiconductor device package; sensing, through a second external connector of the at least one semiconductor device package, a voltage on a second current path including a second semiconductor device of the at least one semiconductor device package; and detecting that a magnitude of current through the first current path is different from a magnitude of current through the second current path based on the voltage on the first current path and the voltage on the second current path.

Example 17 includes the subject matter of Example 16, and wherein the first current path is in parallel with the second current path.

Example 18 includes the subject matter of any of Examples 16 and 17, and wherein during a steady state condition, the voltage on the first current path is equal to the voltage on the second current path, and wherein during a switching or transient load event, the voltage on the first current path is different from the voltage on the second current path.

Example 19 includes the subject matter of any of Examples 16-18, and wherein the first external connector is connected to a source of the first semiconductor device and wherein the second external connector is connected to a source of the second semiconductor device.

Example 20 includes the subject matter of any of Examples 16-19, and wherein the at least one semiconductor device package is a single package comprising the first semiconductor device and the second semiconductor device.

While the concepts of the present disclosure are susceptible to various modifications and alternative forms, specific examples thereof have been shown in the drawings and described herein in detail. However, the concepts of the present disclosure are not limited to the particular forms disclosed, but on the contrary, all modifications, equivalents, and alternatives consistent with the present disclosure and the appended claims are also covered. Moreover, all examples described herein may be combined in any manner.

1. A system comprising:
a first current path comprising a first discrete semiconductor device, the first discrete semiconductor device comprising a first external connector to output a first voltage on the first current path;
a second current path comprising a second discrete semiconductor device, the second discrete semiconductor device comprising a second external connector to output a second voltage on the second current path; and
a detector coupled to the first external connector and the second external connector, the detector comprising circuitry to detect that a magnitude of current through the first current path is different from a magnitude of current through the second current path based on the first voltage and the second voltage.

2. The system of claim 1, further comprising circuitry to perform an action to protect the first discrete semiconductor device or the second discrete semiconductor device responsive to detection of an excessive current condition based on the first voltage and the second voltage.

3. The system of claim 1, wherein the first current path is in parallel with the second current path.

4. The system of claim 1, wherein during a steady state condition, the first voltage is equal to the second voltage, and wherein during a switching or transient load event, the first voltage is different from the second voltage.

5. The system of claim 1, wherein the first external connector is connected to a source terminal of the first discrete semiconductor device and the second external connector is connected to a source terminal of the second discrete semiconductor device.

6. The system of claim 1, wherein the first external connector is connected to a drain terminal of the first discrete semiconductor device and the second external connector is connected to a drain terminal of the second discrete semiconductor device.

7. The system of claim 1, wherein the first discrete semiconductor device is one of a metal-oxide-semiconductor field-effect transistor (MOSFET), a junction field-effect transistor (JFET), an insulated gate bipolar transistor (IGBT), a bipolar junction transistor (BJT), or a thyristor.

8. A semiconductor device package comprising:
at least one semiconductor device; and
a plurality of connectors to connect the at least one semiconductor device to circuitry external to the at least one semiconductor device, wherein the plurality of connectors include:
a first connector connected to a first portion of the at least one semiconductor device, the first connector to output a voltage of the first portion of the at least one semiconductor device; and
a second connector connected to a second portion of the at least one semiconductor device, the second connector to output a voltage of the second portion of the at least one semiconductor device, wherein relative magnitudes of the voltage of the first portion and the voltage of the second portion are indicative of relative currents through the first portion and the second portion.

9. The semiconductor device package of claim 8, wherein the at least one semiconductor device comprises a transistor and wherein a source terminal of the transistor comprises the first portion and the second portion.

10. The semiconductor device package of claim 8, wherein the at least one semiconductor device comprises a transistor and wherein an emitter terminal of the transistor comprises the first portion and the second portion.

11. The semiconductor device package of claim 8, wherein the first connector is connected to a first portion of a conductive pad, and wherein a third connector of the plurality of connectors is connected to a second portion of the conductive pad.

12. The semiconductor device package of claim 11, wherein the second connector is connected to a first portion of a second conductive pad, and wherein a fourth connector of the plurality of connectors is connected to a second portion of the second conductive pad.

13. The semiconductor device package of claim 12, wherein the second conductive pad has a smaller top surface area than the conductive pad.

14. The semiconductor device package of claim 8, wherein the at least one semiconductor device comprises a first MOSFET and a second MOSFET, and wherein the first connector is connected to a source of the first MOSFET and the second connector is connected to a source of the second MOSFET.

15. The semiconductor device package of claim 8, wherein the at least one semiconductor device comprises a MOSFET and a Schottky barrier diode, and wherein the first connector is connected to a source of the MOSFET and the second connector is connected to an anode of the Schottky barrier diode.

16. A method comprising:
sensing, through a first external connector of at least one semiconductor device package, a voltage on a first current path including a first semiconductor device of the at least one semiconductor device package;
sensing, through a second external connector of the at least one semiconductor device package, a voltage on a second current path including a second semiconductor device of the at least one semiconductor device package; and
detecting that a magnitude of current through the first current path is different from a magnitude of current through the second current path based on the voltage on the first current path and the voltage on the second current path.

17. The method of claim 16, wherein the first current path is in parallel with the second current path.

18. The method of claim 16, wherein during a steady state condition, the voltage on the first current path is equal to the voltage on the second current path, and wherein during a switching or transient load event, the voltage on the first current path is different from the voltage on the second current path.

19. The method of claim 16, wherein the first external connector is connected to a source of the first semiconductor device and wherein the second external connector is connected to a source of the second semiconductor device.

20. The method of claim 16, wherein the at least one semiconductor device package is a single package comprising the first semiconductor device and the second semiconductor device.
